(19) United States
(12) Patent Application Publication
(10) Pub. No.: US 2023/0169919 A1
(43) Pub. Date: Jun. 1, 2023

(54) DISPLAY APPARATUS AND DISPLAY PANEL THEREOF

(71) Applicant: LG Display Co., Ltd., Scott (KR)

(72) Inventors: Hye Rin Kim, Paju-si (KR); Kyu Han Yoon, Paju-si (KR); Kyeong Seob Kwon, Paju-si (KR); In Seop Kim, Paju-si (KR)

(21) Appl. No.: 17/973,453

(22) Filed: Oct. 25, 2022

(30) Foreign Application Priority Data
Nov. 30, 2021 (KR) 10-2021-0168210

(51) Int. Cl. G09G 3/3233; H10K 59/88

(52) U.S. Cl. CPC G09G 3/3233; H01L 27/3223; G09G 2300/0426; G09G 2300/0452; G09G 2310/0202; G09G 2300/0413; G09G 2310/08; G09G 2300/0842; H01L 27/3244

(57) ABSTRACT

A display apparatus and a display panel thereof are provided. The display apparatus includes a first driving circuit supplying a gate signal through a first line at a first time and supplying the gate signal through a second line at a second time, a display panel including a first pixel including a first subpixel connected to the first line, a second subpixel connected to the second line, and a third subpixel connected to the first line, and a second driving circuit supplying a data signal to the first subpixel and the third subpixel at the first time and supplying the data signal to the second subpixel at the second time. Accordingly, each of subpixels configuring a pixel may be connected to a gate line adjacent thereto, and thus, short circuit may be prevented from occurring when all of subpixels are connected to one gate line.

### CROSS-REFERENCE TO RELATED APPLICATIONS

This application claims the benefit of the Korean Patent Application No. 10-2021-0168210 filed on Nov. 30, 2021, which is hereby incorporated by reference as if fully set forth herein. BACKGROUND

### TECHNICAL FIELD

The present disclosure relates to a display apparatus and a display panel thereof, which enhance display quality.

### DESCRIPTION OF THE RELATED ART

As technology advances, various display apparatuses having excellent performance such as thinness, lightness, and low power consumption are being developed. Detailed examples of display apparatuses may include organic light emitting diode (OLED) display apparatuses.

OLED display apparatuses are self-emitting display apparatuses which excite an organic compound to emit light. Because OLED display apparatuses do not need a backlight used in liquid crystal display (LCD) apparatuses, lightness and thinness may be implemented, and moreover, a manufacturing process may be simplified. Also, OLED display apparatuses may be manufactured at a low temperature, may have a fast response time of 1 millisecond (ms) or less, and may have characteristics such as low power consumption, a wide viewing angle, and high contrast, and thus, are being widely used.

In OLED display apparatuses, a pixel which is a basic unit configuring a displayed image is configured with a plurality of subpixels. Each of the plurality of subpixels may include various elements for emitting light, in addition to an anode and a cathode. Based on a structure and arrangement of such subpixels, the display quality of OLED display apparatuses may be determined.

Recently, with the advancement of technology, display apparatuses are used in various areas of life, and thus, the shapes or desired functions of display apparatuses are being diversified. Therefore, a pixel structure having various shapes in addition to a single tetragonal shape of a pixel of the related art has been proposed, and research for modifying a configuration of display apparatuses on the basis of a changed pixel structure is being actively done.

### BRIEF SUMMARY

Embodiments of the present disclosure may provide a display apparatus and a display panel thereof, which reduce a risk of disconnection through a modification of a connection structure of a subpixel, thereby enhancing display quality.

The benefits of the present disclosure are not limited to the aforesaid, but other benefits not described herein will be clearly understood by those skilled in the art from descriptions below.

To achieve these benefits and other advantages and in accordance with the purpose of the disclosure, as embodied and broadly described herein, a display apparatus includes a first driving circuit supplying a gate signal through a first line at a first time and supplying the gate signal through a second line at a second time, a display panel including a first pixel including a first subpixel connected to the first line, a second subpixel connected to the second line, and a third subpixel connected to the first line, and a second driving circuit supplying a data signal to the first subpixel and the third subpixel at the first time and supplying the data signal to the second subpixel at the second time.

In another aspect of the present disclosure, a display panel includes a first line transferring a gate signal at a first time and a second line transferring the gate signal at a second time, a first pixel including a first subpixel connected to the first line, a second subpixel connected to the second line, and a third subpixel connected to the first line, and a third line transferring a data signal to the first subpixel and the third subpixel at the first time and a fourth line transferring the data signal to the second subpixel at the second time.

Details of other embodiments will be included in the detailed description of the disclosure and the accompanying drawings.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a block diagram of a display apparatus according to an embodiment of the present disclosure;

FIG. 2 is a diagram illustrating an example of an equivalent circuit of a subpixel of a display apparatus according to an embodiment of the present disclosure;

FIG. 3 is a diagram for describing a subpixel of a display apparatus according to an embodiment of the present disclosure;

FIG. 4 is a conceptual diagram for describing a connection structure of a subpixel of a display apparatus according to an embodiment of the present disclosure;

FIG. 5 is a diagram for describing a signal provided to a display apparatus according to an embodiment of the present disclosure;

FIGS. 6 to 8 are diagrams for describing in more detail a connection structure of a subpixel of a display apparatus according to an embodiment of the present disclosure;

FIG. 9 is a conceptual diagram for describing a connection structure of a subpixel of a display apparatus according to another embodiment of the present disclosure;

FIG. 10 is a diagram for describing a signal provided to a display apparatus according to another embodiment of the present disclosure;

FIGS. 11 to 13 are diagrams for describing in more detail a connection structure of a subpixel of a display apparatus according to another embodiment of the present disclosure; and

FIG. 14 is a diagram for describing a structure and arrangement of a subpixel of a display apparatus according to various embodiments of the present disclosure.

### DETAILED DESCRIPTION

Hereinafter, the present disclosure will be described more fully with reference to the accompanying drawings, in which embodiments of the disclosure are shown. The disclosure may, however, be embodied in many different forms and should not be construed as being limited to the embodiments set forth herein; rather, these embodiments are provided so that this disclosure will be thorough and complete, and will fully convey the concept of the disclosure to those skilled in the art.

Terms used in the present disclosure have been selected as general terms which are widely used at present, in consideration of the functions of the present disclosure, but may be altered according to the intent of an operator of ordinary skill in the art, conventional practice, or introduction of new technology. Also, if there is a term which is arbitrarily selected by the applicant in a specific case, in which case a meaning of the term will be described in detail in a corresponding description portion of the present disclosure. Therefore, the terms should be defined on the basis of the entire content of this specification instead of a simple name of each of the terms.

In this disclosure below, when it is described that one comprises (or includes or has) some elements, it should be understood that it may comprise (or include or has) only those elements, or it may comprise (or include or have) other elements as well as those elements if there is no specific limitation.

The term “at least one of a, b, and c” may include ‘a,’ ‘b,’ ‘c,’ ‘a and b,’ ‘a and c,’ ‘b and c,’ or ‘all of a, b, and c.’ The advantage and feature of the present disclosure and a method for accomplishing the advantage and the feature will be clearly described with reference to embodiments described below in detail in conjunction with the accompanying drawings.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known technology is determined to unnecessarily obscure the important point of the present disclosure, the detailed description will be omitted.

In a case where ‘comprise,’ ‘have,’ and ‘include’ described in the present specification are used, another part may be added unless ‘only˜’ is used. The terms of a singular form may include plural forms unless referred to the contrary. In construing an element, the element is construed as including an error range although there is no explicit description.

In describing a position relationship, for example, when a position relation between two parts is described as ‘on˜,’ ‘over˜,’ ‘under˜,’ and ‘next˜,’ one or more other parts may be disposed between the two parts unless ‘just’ or ‘direct’ is used. A case where an element or a layer is referred to as being ‘on’ another element or layer may include a case where another layer or another element is disposed at a middle portion or directly on another element.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

An area, a length, or a thickness of each element described herein is illustrated for convenience of description, and the present disclosure is not limited to an area and a thickness of each element illustrated in the drawings.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in co-dependent relationship.

Moreover, the terms used henceforth have been defined in consideration of the functions of the present disclosure, and may be altered according to the intent of a user or operator, or conventional practice. Therefore, the terms should be defined on the basis of the entire content of this specification.

A transistor configuring a pixel circuit according to the present disclosure may include one or more of an oxide thin film transistor (oxide TFT), an amorphous silicon thin film transistor (a-Si TFT), and a low temperature poly silicon thin film transistor (LTPS TFT).

In the following embodiments, an organic light emitting diode display apparatus will be briefly described. However, embodiments of the present disclosure are not limited to an organic light emitting diode display apparatus and may be applied to an inorganic light emitting diode display apparatus including an inorganic light emitting material. For example, embodiments of the present disclosure may be applied to a quantum dot display apparatus.

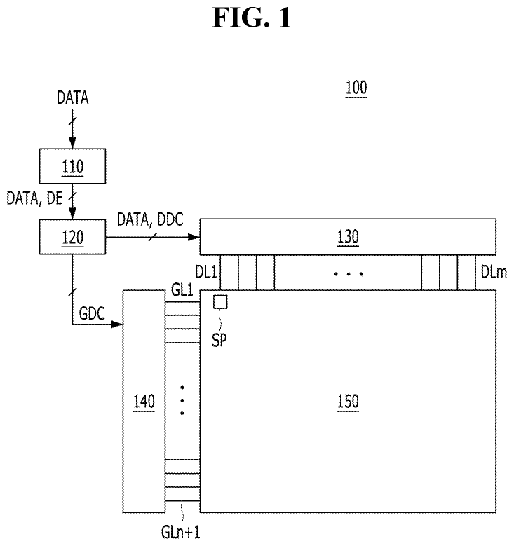

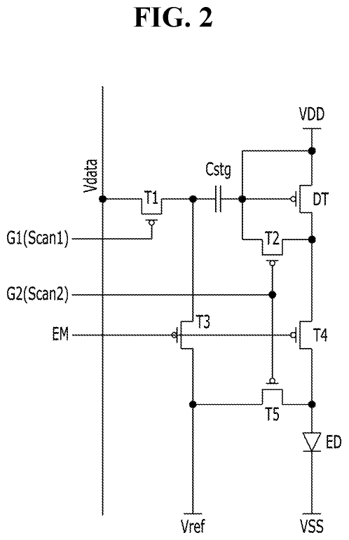

The terms ‘first,’ ‘second,’ and ‘third’ may be terms used for differentiating elements according to embodiments, and embodiments are not limited to such terms. Therefore, although terms are the same terms, the terms may refer to other elements. For example, a first subpixel circuit of FIG. 1 and a second subpixel circuit of FIG. 2 may be terms for differentiating and describing elements in each drawing and may not refer to the same element.

Hereinafter, embodiments of the present disclosure will be described with reference to the drawings.

FIG. 1 is a block diagram of a display apparatus 100 according to an embodiment of the present disclosure.

The display apparatus 100 according to an embodiment of the present disclosure may use an electroluminescent display apparatus. The electroluminescent display apparatus may use an organic light emitting diode (OLED) display apparatus, a quantum-dot light emitting diode display apparatus, or an inorganic light emitting diode display apparatus.

Referring to FIG. 1, the display apparatus 100 may include an image processor 110, a timing controller 120, a data driver 130, a gate driver 140, and a display panel 150.

The image processor 110 may output a data signal DATA and a data enable signal DE supplied from the outside. The image processor 110 may output one or more of a vertical synchronization signal, a horizontal synchronization signal, and a clock signal in addition to the data enable signal DE, but the illustration of the signals is omitted for convenience of description.

The timing controller 120 may be supplied with the data signal DATA and a driving signal including the vertical synchronization signal, the horizontal synchronization signal, and the clock signal or the data enable signal DE from the image processor 110. The timing controller 120 may output a gate timing control signal GDC for controlling an operation timing of the gate driver 140 and a data timing control signal DDC for controlling an operation timing of the data driver 130 on the basis of the driving signal.

The data driver 130 may sample and latch the data signal DATA provided from the timing controller 120 to generate and output a gamma reference voltage, in response to the data timing control signal DDC provided from the timing controller 120. The data driver 130 may output the data signal DATA through data lines DL1 to DLm. The data driver 130 may be implemented as an integrated circuit (IC) type.

The gate driver (or scan driver) 140 may output (or provide) a gate signal (or a scan signal) in response to the gate timing control signal GDC provided from the timing controller 120. The gate driver 140 may output the gate signal through gate lines GL1 to GLn+1. The gate driver 140 may be implemented as an IC type, or may be implemented as a gate-in panel (GIP) type in the display panel 150.

In FIG. 1, an example where the gate driver 140 is disposed at one end of the display panel 150 is illustrated, but the present disclosure is not limited thereto. For example, the gate driver 140 may be provided in plurality, and the plurality of gate drivers 140 may be respectively disposed at both ends of the display panel 150. In this case, the gate drivers 140 disposed at the both ends may simultaneously output the gate signal to one gate line at the both ends, and thus, a signal may be quickly output.

The display panel 150 may display an image on the basis of the data signal DATA and the scan signal respectively supplied from the data driver 130 and the gate driver 140. The display panel 150 may include a subpixel SP which operates to display an image. The display panel 150 may include a plurality of subpixels SP. One pixel may be configured with at least some of a plurality of subpixels. For example, one pixel may include a red subpixel, a green subpixel, and a blue subpixel. As another example, one pixel may include a white subpixel, a red subpixel, a green subpixel, and a blue subpixel. Each subpixel SP may have one or more different emission areas on the basis of an emission characteristic.

FIG. 2 is a diagram illustrating an example of an equivalent circuit of a subpixel of a display apparatus according to an embodiment of the present disclosure.

Referring to FIG. 2, a subpixel SP of a display apparatus according to an embodiment of the present disclosure may include first to fifth switching transistors T1 to T5, a driving transistor DT, a storage capacitor Cstg, and a light emitting device ED.

Here, the light emitting device ED may be a self-emitting device which self-emits light like an OLED, but is not limited thereto.

In the subpixel SP of a display apparatus according to an embodiment of the present disclosure, each of the first to fifth switching transistors T1 to T5 and the driving transistor DT may be a P-type transistor. However, the present disclosure is not limited thereto and at least one of the first to fifth switching transistors T1 to T5 and the driving transistor DT may be an N-type transistor. In this case, a source and a drain of the below-described transistor may switch therebetween in position.

A P-type transistor may be higher in reliability than an N-type transistor. In the P-type transistor, a drain electrode may be fixed to a high level driving voltage VDD, and thus, a current flowing in the light emitting device ED may not be shaken by the storage capacitor Cstg. Accordingly, it may be easy to stably supply a current.

For example, the P-type transistor may be connected to an anode electrode of the light emitting device ED. In this case, when the transistors T4 and T5 connected to the light emitting device ED operate in a saturation region, a constant current may flow regardless of a variation of each of a threshold voltage and a current of the light emitting device ED, and thus, reliability may be relatively high.

In an embodiment, a transistor may be a silicon transistor (for example, a transistor including a polysilicon channel formed by using a low temperature process referred to as LTPS or low temperature polysilicon) formed from a semiconductor such as silicon. However, the present disclosure is not limited thereto, and depending on the case, a transistor may be configured as an oxide transistor. The oxide transistor may have a feature where a leakage current is relatively lower than a silicon transistor, and thus, in a case where a transistor is implemented by using the oxide transistor, a current may be prevented from being leaked from a gate electrode of the driving transistor DT, and thus, an image-quality defect such as flicker may be reduced.

A gate electrode of the first switching transistor T1 may be supplied with a first scan signal Scan1. A source electrode of the first switching transistor T1 may be supplied with a data voltage Vdata. A drain electrode of the first switching transistor T1 may be connected to the storage capacitor Cstg.

A gate electrode of the second switching transistor T2 may be supplied with a second scan signal Scan2. The second switching transistor T2 may be turned on by the second scan signal Scan2 and may control an operation of the driving transistor DT on the basis of the high level driving voltage VDD stored in the storage capacitor Cstg.

A gate electrode of the third switching transistor T3 may be supplied with an emission signal EM. A source electrode of the third switching transistor T3 may be supplied with a reference voltage Vref.

A gate electrode of the fourth switching transistor T4 may be supplied with the emission signal EM. A source electrode of the fourth switching transistor T4 may be connected to a drain electrode of the driving transistor DT. A drain electrode of the fourth switching transistor T4 may be connected to the anode electrode of the light emitting device ED. The fourth switching transistor T4 may be turned on by the emission signal EM and may supply a driving current to the anode electrode of the light emitting device ED.

A gate electrode of the fifth switching transistor T5 may be supplied with the second scan signal Scan2. A source electrode of the fifth switching transistor T5 may be supplied with the reference voltage Vref. A drain electrode of the fifth switching transistor T5 may be connected to the anode electrode of the light emitting device ED.

The gate electrode of the driving transistor DT may be connected to the storage capacitor Cstg, and a drain electrode thereof may be connected to the source electrode of the second switching transistor T2. A source electrode of the driving transistor DT may be supplied with the high level driving voltage VDD.

The anode electrode of the light emitting device ED may be connected to a drain electrode of the fifth switching transistor T5 and a drain electrode of the fourth switching transistor T4. A low level driving voltage VSS may be supplied to a cathode electrode of the light emitting device ED.

In an embodiment, when the reference voltage Vref is supplied to the anode electrode of the light emitting device ED in a state where the fourth switching transistor T4 disposed between the anode electrode of the light emitting device ED and the driving transistor DT and controlled by the emission signal EM is turned on, the anode electrode of the light emitting device ED may be reset.

In FIG. 2, the subpixel SP including six transistors DT, T1, T2, T3, T4, and T5 and one capacitor Cstg is illustrated for example. However, the present disclosure is not limited thereto, and the structure and number of capacitors and transistors configuring the subpixel SP may be variously modified. Also, in an embodiment, each of a plurality of subpixels SP may be implemented in the same structure, or some of the plurality of subpixels SP may be implemented in different structures.

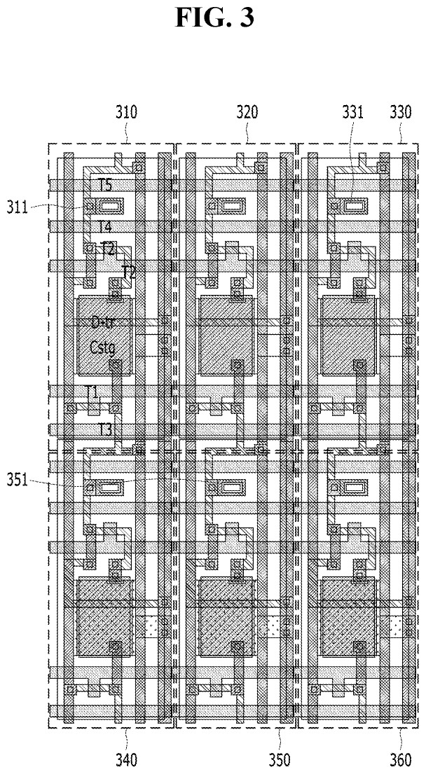

FIG. 3 is a diagram for describing a subpixel of a display apparatus according to an embodiment of the present disclosure. In detail, FIG. 3 illustrates an example where a circuit corresponding to a subpixel SP is disposed at a portion of a display panel. In FIG. 3, an element corresponding to a light emitting device of the subpixel SP is omitted.

A first region 310 of FIG. 3 may be a region where an element, corresponding to a subpixel SP having a state where a light emitting device is excluded in the equivalent circuit described above with reference to FIG. 2, is provided. A second region 320, a third region 330, a fourth region 340, a fifth region 350, and a sixth region 360 may each correspond to a region where an element, corresponding to a subpixel SP having a state where a light emitting device is excluded, is provided.

According to the first region 310 of FIG. 3, a circuit of the subpixel may include first to fifth switching transistors T1 to T5, a driving transistor DT, and a storage capacitor Cstg. As in the first region 310, the circuit elements of the subpixel may be arranged as a matrix type. The circuit elements of the subpixel may be respectively arranged in the second region 320, the third region 330, the fourth region 340, the fifth region 350, and the sixth region 360.

In an embodiment, one subpixel may correspond to one light emitting device. In this case, a circuit element corresponding to each of the first to sixth regions 310 to 360 may be connected to another subpixel.

In an embodiment, a subpixel corresponding to one pixel may be provided in plurality. For example, one subpixel may be configured with a first subpixel, a second subpixel, and a third subpixel. In this case, the first subpixel, the second subpixel, and the third subpixel may emit pieces of light having different colors, and based thereon, one pixel may implement various colors. For example, the first subpixel may emit red light, the second subpixel may emit green light, and the third subpixel may emit blue light. In this manner, each subpixel may need a data signal and a gate signal for emitting light. That is, when the data signal and the gate signal are applied to one subpixel, the subpixel may emit light. Accordingly, the subpixel may be supplied with the gate signal and the data signal on the basis of being connected to the circuit element illustrated in FIG. 3.

In an embodiment, the first subpixel configuring one pixel may be connected to a circuit element corresponding to the first region 310, the second subpixel may be connected to a circuit element corresponding to the fifth region 350, and the third subpixel may be connected to a circuit element corresponding to the third region 330. In the first region 310, a point at which the first subpixel is connected to a circuit element may correspond to a first point 311. In the third region 330, a point at which the third subpixel is connected to a circuit element may correspond to a third point 331. In the fifth region 350, a point at which the first subpixel is connected to a circuit element may correspond to a fifth point 351.

In this case, a subpixel of a pixel which differs from a pixel corresponding to the first region 310 and the third region 330 may be connected to the second region 320 disposed between the first region 310 and the third region 330. For example, a first subpixel of a first pixel may be connected to the first region 310, and a second subpixel of the first pixel may be connected to the third region 330. A third subpixel of a second pixel may be connected to the second region 320. However, even when a subpixel connected to the second region 320 is included in a pixel which differs from a pixel including a subpixel of each of the first region 310 and the third region 330, at least a portion (for example, a portion of an anode) of a light emitting device of a pixel corresponding to the first region 310 and the third region 330 may be disposed in the second region 320.

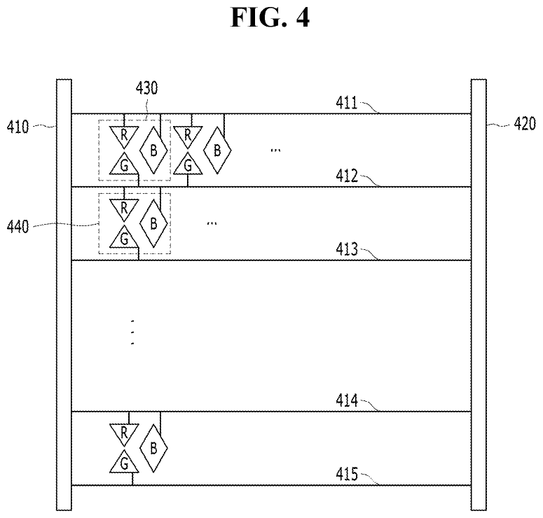

FIG. 4 is a conceptual diagram for describing a connection structure of a subpixel of a display apparatus according to an embodiment of the present disclosure. FIG. 4 conceptually illustrates some elements of the display apparatus.

Referring to FIG. 4, the display apparatus may include first driving circuits 410 and 420, a pixel (for example, a first pixel 430 and a second pixel 440), and a plurality of lines 411 to 415.

In an embodiment, a pixel may be disposed in a display area of the display apparatus. The first driving circuits 410 and 420 may be separated from each other and disposed at both ends of the display area (for example, a left portion and a right portion of a front surface of the display apparatus). However, the present disclosure is not limited thereto, and the first driving circuits 410 and 420 may be provided as one body or may be divided into two or more circuits and disposed at different positions of the display apparatus.

The first driving circuits 410 and 420 may each include a gate driver. In this case, each of the first driving circuits 410 and 420 may provide a gate signal (or a scan signal) to a pixel.

In an embodiment, a pixel may include a plurality of subpixels R, G, and B. The plurality of subpixels may emit pieces of light having different colors. For example, a red subpixel may emit red (R) light, a green subpixel may emit green (G) light, and a blue subpixel may emit blue (B) light.

Depending on the case, the pixel may further include a subpixel emitting light having a color other than R, G, and B. For example, the pixel may further include a white subpixel which emits white (W) light. Alternatively, at least one subpixel included in the pixel may emit light having a color other than R, G, and B. For example, the first subpixel may emit pink (P) light instead of red light.

In an embodiment, a virtual line which connects centers of a red subpixel R, a green subpixel G, and a blue subpixel B may be illustrated in a triangular shape. A detailed example relevant thereto may refer to FIG. 14.

According to an embodiment, the red subpixel R may be arranged upward from the green subpixel G in a y axis (e.g., in a first axis direction or vertical axis direction along which the plurality of lines 411 to 415 are arranged). That is, the blue subpixel B may be arranged in parallel with the red subpixel R or the green subpixel G in an x axis (e.g., in a second axis direction or horizontal axis direction along which the plurality of lines 411 to 415 extend).

Each of the plurality of lines 411 to 415 may connect the first driving circuits 410 and 420 to the pixel. In an embodiment, each of the plurality of lines (for example, first to fifth lines) 411 to 415 may connect the first driving circuits 410 and 420 to at least one of subpixels adjacent thereto. For example, the first line 411 may connect at least a portion of the first pixel 430 to the first driving circuits 410 and 420, and the second line 412 may connect another portion of the first pixel 430 and at least a portion of the second pixel 440 to the first driving circuits 410 and 420.

In an embodiment, signals of the first driving circuits 410 and 420 may be provided to the pixel through the plurality of lines 411 to 415. The signals of the first driving circuits 410 and 420 may include, for example, a gate signal (or a scan signal). The signals of the first driving circuits 410 and 420 may be provided sequentially up to the fifth line 415 from the first line 411. For example, when a signal is provided to the first line 411 at an n time, a signal may be provided to the second line 412 at an n+1 time, and a signal may be provided to the fifth line 415 at an n+5 time.

In this case, one time may be a predetermined or selected time interval. For example, when an n time is a reference time (or a specific time), an added 1 time may correspond to the predetermined or selected time interval (for example, 0.01 sec). The predetermined or selected time interval is not limited to an embodiment of the present disclosure and may apply various time intervals.

In an embodiment, the first line 411 may correspond to a line which is disposed at an uppermost end of a region where a pixel is provided. In this case, a subpixel (or a pixel) may not be at an upper end of the first line 411. Accordingly, a subpixel connected to the first line 411 may include at least one of subpixels which are arranged at a lower end of the first line 411.

For example, the subpixel connected to the first line 411 may correspond to a subpixel arranged within a certain distance range from the first line 411 among the subpixels which are arranged at a lower end of the first line 411. In more detail, for example, the subpixel connected to the first line 411 may include a red subpixel R and a blue subpixel B of the first pixel 430.

In an embodiment, a green subpixel G of the first pixel 430 which is not connected to the first line 411 may be connected to the second line 412. Also, the second line 412 may be further connected to a subpixel arranged within a certain distance range from the second line 412 among the subpixels of the second pixel 440. For example, the second line 412 may be connected to a red subpixel R and a blue subpixel B of the second pixel 440. A subpixel, which is not connected to the second line 412, of the subpixels of the second pixel 440 may be connected to the third line 413.

In an embodiment, the fifth line 415 may be a line which is disposed at a lowermost end. In this case, a pixel may not be disposed at a lower end of the fifth line 415. The fifth line 415, as illustrated, may be connected to one of subpixels arranged at an upper end of the fifth line 415. For example, the fifth line 415 may be connected to a green subpixel G of a pixel disposed at the upper end of the fifth line 415.

Furthermore, in an embodiment of the present disclosure, the term representing a direction (for example, the terms such as an upper end, a lower end, a left side, and a right side) may represent another direction according to embodiments. For example, an upper end may denote a left side and a lower end may denote a right side, but an embodiment is not limited thereto.

Although not shown, the display apparatus may further include a second driving circuit. The second driving circuit may provide a data signal to a pixel. For example, the second driving circuit may be connected to a pixel through a line (hereinafter referred to as a data line) which transfers the data signal. The second driving circuit may provide the data signal to a pixel through a data line. In this case, the data signal may be provided for each subpixel. For example, the second driving circuit may provide the data signal to a red subpixel R and a blue subpixel B at a first time and may provide the data signal to a green subpixel G at a second time.

Here, the first time and the second time may correspond to sequential times having the predetermined or selected time interval. For example, when the n time corresponds to the first time, the n+1 time may correspond to the second time.

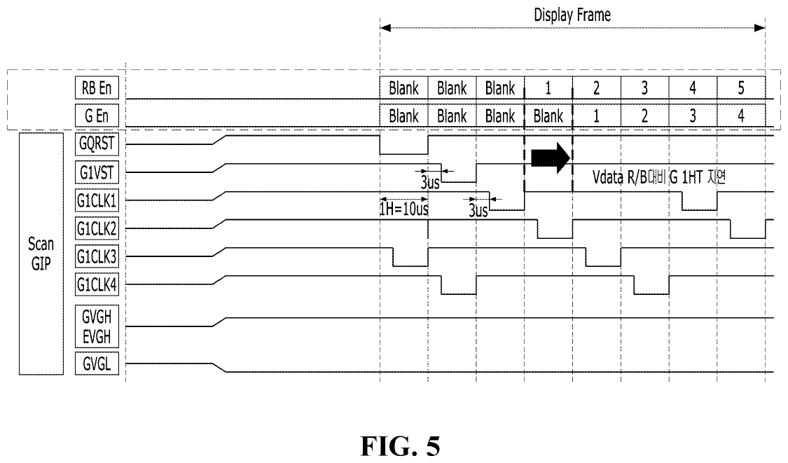

FIG. 5 is a diagram for describing a signal provided to a display apparatus according to an embodiment of the present disclosure. In detail, FIG. 5 is a diagram for describing a timing of a signal provided to a pixel by a first driving circuit in the display apparatus according to an embodiment of the present disclosure.

Referring to FIG. 5, a period where a pixel of the display apparatus emits light may be referred to as a display frame. The display frame may be divided into a plurality of sub-frames. In this case, one frame may correspond to one time described above with reference to FIG. 4. For example, an n time may correspond to an n^{th} sub-frame, and an n+1 time may correspond to an n+1^{th} sub-frame. One sub-frame may correspond to 10 μs, but is not limited thereto.

Referring to FIG. 5, in an embodiment, a first driving circuit (for example, a gate driver) may provide signals GQRST, G1VST, G1CLK1 to G1CLK4, GVGH, and GVGL in the display frame. Here, GQRST may be a signal for initializing a first driving circuit, G1VST may be a signal for turning on a first stage of a driving circuit, and G1CLK1 to G1CLK4 may be synchronization signals. GVGH may be a high signal and may be a signal for turning off an internal transistor of a driving circuit, and GVGL may be a low signal and may be a signal for turning on the internal transistor of the driving circuit.

In the display frame, a second driving circuit (for example, a data driver) may provide a data signal to each of subpixels. For example, the second driving circuit may provide a data signal (RB En of FIG. 5) to a red subpixel R and a blue subpixel B at a first time. The second driving circuit may provide a data signal (G En of FIG. 5) to a green subpixel G at a second time. The second time may correspond to a time at which one sub-frame delays from the first time. That is, when the first time is an n^{th} sub-frame, the second time may correspond to an n+1^{th} sub-frame.

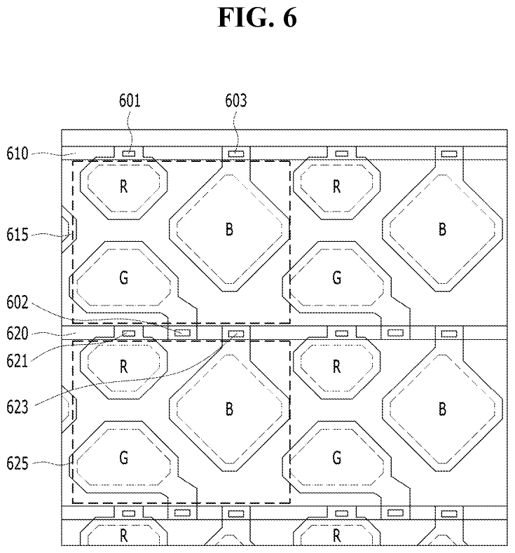

FIG. 6 is a diagram for describing a connection of a subpixel to a line disposed at an uppermost end among a plurality of lines of a first driving circuit.

Referring to FIG. 6, a first line 610 may be a line which is disposed at an uppermost end of the first driving circuit. For example, when a plurality of lines connecting the first driving circuit to a pixel are arranged with respect to a y axis, the first line 610 may correspond to a line disposed at an uppermost end among the plurality of lines. A second line 620 may correspond to a line disposed more downward than the first line 610. As another example, when the number of lines connected to the first driving circuit is a k number, the first line 610 may correspond to a first line, and the second line 620 may correspond to a second line.

In an embodiment, a dummy pixel may be disposed more upward than the first line 610. The first line 610 may be connected to at least one subpixel included in each of pixels arranged more downward than the first line 610. For example, the first line 610 may be connected to a red subpixel R and a blue subpixel B of a first pixel 615 arranged more downward than the first line 610.

Portions (for example, a first contact hole 601 and a third contact hole 603), at which the red subpixel R and the blue subpixel B of the first pixel 615 contact the first line 610, may be disposed to correspond to the arrangement of the red subpixel R and the blue subpixel B in an x axis. That is, when the red subpixel R is disposed at a left side and the blue subpixel B is disposed at a right side, the first contact hole 601 may be disposed at a left side in the first line 610, and the third contact hole 603 may be disposed at a right side in the first line 610.

Although not shown, according to an embodiment, a dummy pixel may be disposed at an upper end of the first line 610. In this case, the dummy pixel may be connected to the first line 610, and a portion at which the dummy pixel contacts the first line 610 may be disposed in the first line 610. For example, a portion at which the dummy pixel contacts the first line 610 may be disposed between the first contact hole 601 and the third contact hole 603.

In an embodiment, the second line 620 may be a line which is disposed at a lower end of the first line 610. The second line 620 may provide a signal (for example, a gate signal) provided from the first driving circuit at a time at which the signal delays by one sub-frame compared to the first line 610.

In an embodiment, a green subpixel G of the first pixel 615 may be connected to the second line 620. In this case, a portion (i.e., the second contact hole 602) at which the green subpixel G contacts the second line 620 may be disposed in the second line 620.

Moreover, in an embodiment, a red subpixel R and a blue subpixel B of a second pixel 625 disposed at a lower end of the second line 620 may be further connected to the second line 620. In this case, the second contact hole 602 of the green subpixel G may be disposed between a fourth contact hole 621 of the red subpixel R and a sixth contact hole 623 of the blue subpixel B in the second line 620.

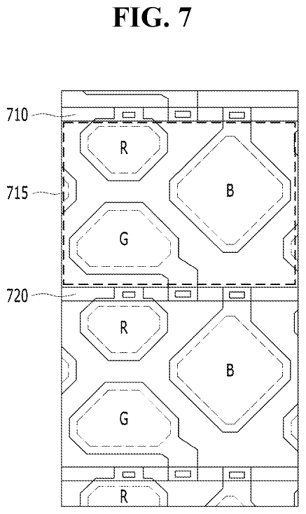

FIG. 7 is a diagram for describing a connection relationship between a subpixel and a line disposed at a middle portion among the plurality of lines.

Referring to FIG. 7, when the number of lines connected to a first driving circuit is a k number, a third line 710 may be an n^{th} (where n is a natural number which is less than k) line of the plurality of lines of the first driving circuit, and a fourth line 720 may be an n+1^{th} line of the plurality of lines of the first driving circuit. In this case, as illustrated, a red subpixel R and a blue subpixel B of a third pixel 715 disposed between the third line 710 and the fourth line 720 may be connected to the third line 710, and a green subpixel G of the third pixel 715 may be connected to the fourth line 720.

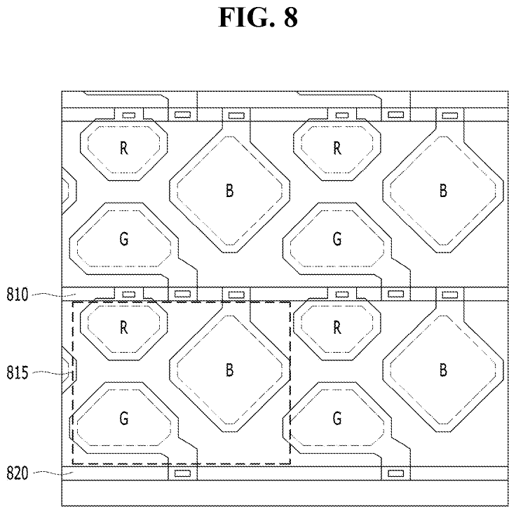

FIG. 8 is a diagram for describing a connection relationship between a subpixel and a line disposed at a lowermost end among the plurality of lines.

Referring to FIG. 8, when the number of lines connected to the first driving circuit is a k+1 number, a fifth line 810 may correspond to a k^{th} line, and a sixth line 820 may correspond to a k+1^{th} line. In this case, a red subpixel R and a blue subpixel B of a fourth pixel 815 disposed between the fifth line 810 and the sixth line 820 may be connected to the fifth line 810, and a green subpixel G of the fourth pixel 815 may be connected to the sixth line 820.

A pixel capable of emitting light may not be disposed under the sixth line 820. Therefore, the sixth line 820 may be connected to only a green subpixel G of a pixel disposed adjacent to the sixth line 820, including the fourth pixel 815. In this case, a contact hole connected to a green subpixel G disposed adjacent to the sixth line 820 may be disposed in the sixth line 820. A contact hole connected to a red subpixel R and a blue subpixel B may be omitted in the sixth line 820.

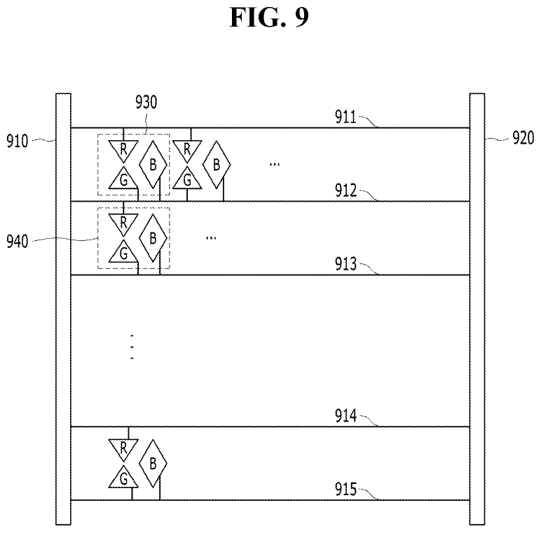

FIG. 9 is a conceptual diagram for describing a connection structure of a subpixel of a display apparatus according to another embodiment of the present disclosure. FIG. 9 relates to an embodiment differentiated from FIG. 4 and conceptually illustrates some elements of the display apparatus according to the present disclosure. Hereinafter, in FIG. 9, details which are the same or similar to the above-described details may be omitted.

Referring to FIG. 9, the display apparatus may include first driving circuits 910 and 920 divided into at least two portions, a pixel (for example, a first pixel 930 and a second pixel 940), and a plurality of lines 911 to 915.

In an embodiment, the pixel 930 and 940 may be disposed in a display area of the display apparatus. The first driving circuits 910 and 920 may be separated from each other and disposed at both ends of the display area (for example, a left portion and a right portion of a front surface of the display apparatus). However, the present disclosure is not limited thereto, and the first driving circuits 910 and 920 may be provided as one body or may be divided into two or more circuits and disposed at different positions of the display apparatus.

The first driving circuits 910 and 920 may each include a gate driver. In this case, each of the first driving circuits 910 and 920 may provide a gate signal (or a scan signal) to the pixel.

In an embodiment, the pixel may include a plurality of subpixels R, G, and B. The plurality of subpixels may emit pieces of light having different colors. For example, a red subpixel may emit red (R) light, a green subpixel may emit green (G) light, and a blue subpixel may emit blue (B) light.

Each of the plurality of lines 911 to 915 may connect the first driving circuits 910 and 920 to the pixel. In an embodiment, each of the plurality of lines (for example, first to fifth lines) 911 to 915 may connect the first driving circuits 910 and 920 to at least one of subpixels adjacent thereto. For example, the first line 911 may connect at least a portion of the first pixel 930 to the first driving circuits 910 and 920, and the second line 912 may connect another portion of the first pixel 930 and at least a portion of the second pixel 940 to the first driving circuits 910 and 920.

In an embodiment, the first line 911 may correspond to a line which is disposed at an uppermost end of a region where the pixel is provided. In this case, a subpixel (or a pixel) may not be at an upper end of the first line 911. Accordingly, a subpixel connected to the first line 911 may include at least one of subpixels which are arranged at a lower end of the first line 911.

For example, the subpixel connected to the first line 911 may correspond to a subpixel arranged within a certain distance range from the first line 911 among the subpixels which are arranged at a lower end of the first line 911. In more detail, for example, the subpixel connected to the first line 911 may include a red subpixel R and a blue subpixel B of the first pixel 930. In this case, a subpixel which is not connected to the first line 911 among subpixels included in the first pixel 930 may be connected to the second line 912.

As another example, a subpixel connected to the first line 911 may correspond to a subpixel, where a distance from the first line 911 to a center point of the subpixel is within a certain distance range, of subpixels disposed at a lower end of the first line 911. In this case, a subpixel, where a distance from the first line 911 to a center point of the subpixel is greater than a certain distance range, of the subpixels disposed at the lower end of the first line 911 may be connected to the second line 912.

In an embodiment, the fifth line 915 may be a line which is disposed a lowermost end. In this case, a pixel may not be disposed at a lower end of the fifth line 915. The fifth line 915, as illustrated, may be connected to one of subpixels arranged at an upper end of the fifth line 915. For example, the fifth line 915 may be connected to a green subpixel G of a pixel disposed at the upper end of the fifth line 915.

Although not shown, the display apparatus may further include a second driving circuit. The second driving circuit may provide a data signal to a pixel. For example, the second driving circuit may be connected to a pixel through a line (hereinafter referred to as a data line) which transfers the data signal. The second driving circuit may provide the data signal to a pixel through a data line. In this case, the data signal may be provided for each subpixel. For example, the second driving circuit may provide the data signal to a red subpixel R and a blue subpixel B at a first time and may provide the data signal to a green subpixel G at a second time.

Here, the first time and the second time may correspond to sequential times having the predetermined or selected time interval. For example, when the n time corresponds to the first time, the n+1 time may correspond to the second time.

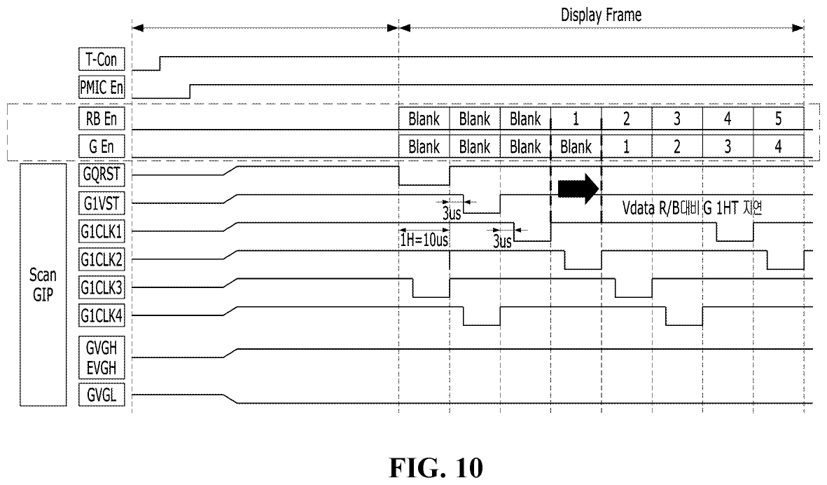

FIG. 10 is a diagram for describing a signal provided to a display apparatus according to another embodiment of the present disclosure. In detail, FIG. 10 is a diagram for describing a timing of a signal provided to a pixel by a first driving circuit in the display apparatus according to another embodiment of the present disclosure. Hereinafter, details which are the same or similar to details described above with reference to FIG. 5 may be omitted.

Referring to FIG. 10, a period where a pixel of the display apparatus emits light may be referred to as a display frame. The display frame may be divided into a plurality of sub-frames. In this case, one frame may correspond to one time described above with reference to FIG. 9. For example, an n time may correspond to an n^{th} sub-frame, and an n+1 time may correspond to an n+1^{th} sub-frame. One sub-frame may correspond to 10 μs, but is not limited thereto.

In the display frame, a second driving circuit (for example, a data driver) may provide a data signal to each of subpixels. For example, the second driving circuit may provide a data signal (R En of FIG. 10) to a red subpixel R at a first time. The second driving circuit may provide a data signal (BG En of FIG. 10) to a green subpixel G and a blue subpixel B at a second time. The second time may correspond to a time at which one sub-frame delays from the first time. That is, when the first time is an n^{th} sub-frame, the second time may correspond to an n+1^{th} sub-frame.

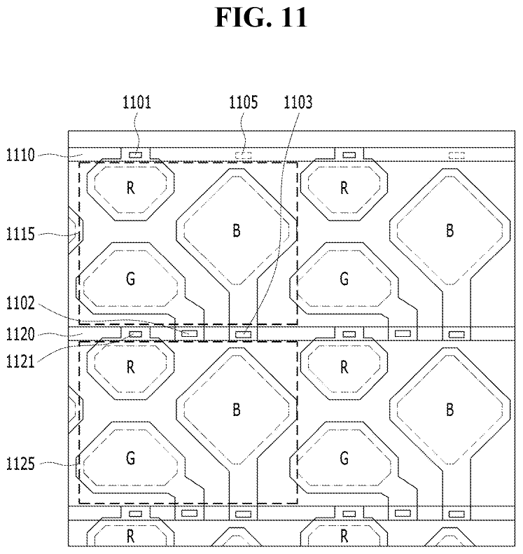

FIG. 11 is a diagram for describing a connection of a subpixel to a line disposed at an uppermost end among a plurality of lines of a first driving circuit.

Referring to FIG. 11, a first line 1110 may be a line which is disposed at an uppermost end of the first driving circuit. For example, when a plurality of lines connecting the first driving circuit to a pixel are arranged with respect to a y axis, the first line 1110 may correspond to a line disposed at an uppermost end among the plurality of lines. A second line 1120 may correspond to a line disposed more downward than the first line 1110. As another example, when the number of lines connected to the first driving circuit is a k number, the first line 1110 may correspond to a first line, and the second line 1120 may correspond to a second line.

In an embodiment, a dummy pixel may be disposed more upward than the first line 1110. The first line 1110 may be connected to at least one subpixel included in each of pixels arranged more downward than the first line 1110. For example, the first line 1110 may be connected to a red subpixel R and a blue subpixel B of a first pixel 1115 arranged more downward than the first line 1110.

Although not shown, according to an embodiment, a dummy pixel may be disposed at an upper end of the first line 1110. In this case, the dummy pixel may be connected to the first line 1110, and a portion at which the dummy pixel contacts the first line 1110 may be disposed in the first line 1110. For example, a portion at which the dummy pixel contacts the first line 1110 may be disposed at a right side (for example, a first point 1105) of a first contact hole 1101.

In an embodiment, a green subpixel G and a blue subpixel B of the first pixel 1115 may be connected to the second line 1120. In this case, a second contact hole 1102 which is a portion at which the green subpixel G contacts the second line 1120 and a third contact hole 1103 which is a portion at which the blue subpixel B contacts the second line 1120 may be disposed in the second line 1120.

Moreover, in an embodiment, a red subpixel R of a second pixel 1125 disposed at a lower end of the second line 1120 may be further connected to the second line 1120. In this case, a fourth contact hole 1121 of a red subpixel R in the second line 1120 may be disposed at a left side of the second contact hole 1102 of the green subpixel G.

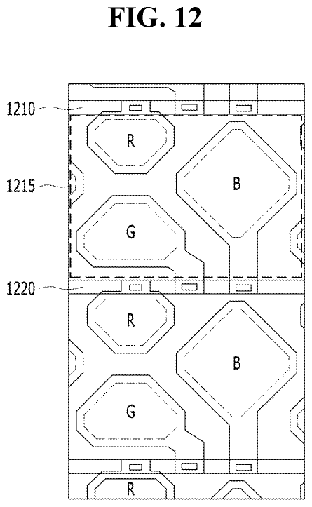

FIG. 12 is a diagram for describing a connection relationship between a subpixel and a line disposed at a middle portion among the plurality of lines. Hereinafter, details which are the same or similar to details described above with reference to FIG. 7 may be omitted.

Referring to FIG. 12, when the number of lines connected to a first driving circuit is a k number, a third line 1210 may be an n^{th} (where n is a natural number which is less than k) line of the plurality of lines of the first driving circuit, and a fourth line 1220 may be an n+1^{th} line of the plurality of lines of the first driving circuit. In this case, as illustrated, a red subpixel R of a third pixel 1215 disposed between the third line 1210 and the fourth line 1220 may be connected to the third line 1210, and a green subpixel G and a blue subpixel B of the third pixel 1215 may be connected to the fourth line 1220.

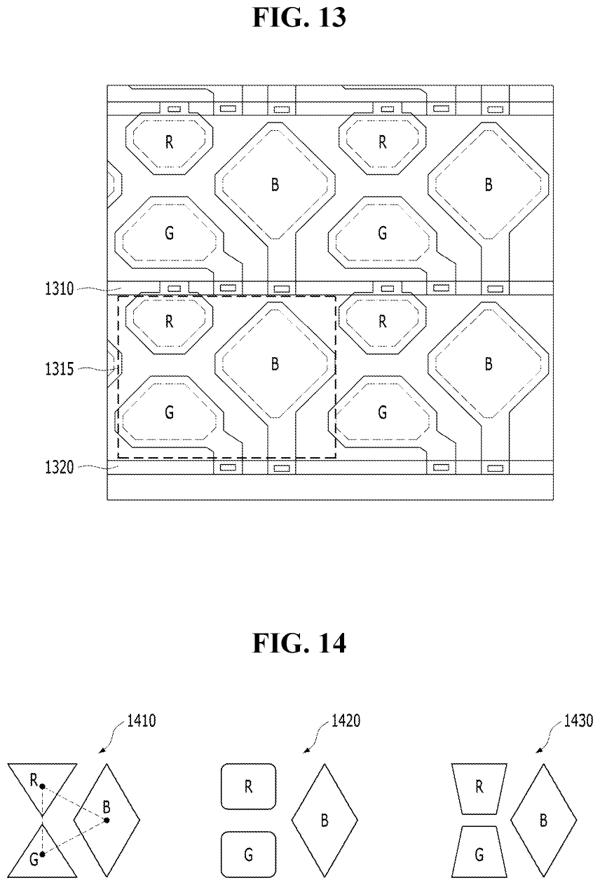

FIG. 13 is a diagram for describing a connection relationship between a subpixel and a line disposed at a lowermost end among the plurality of lines.

Referring to FIG. 13, when the number of lines connected to the first driving circuit is a k number, a fifth line 1310 may correspond to a k−1^{th} line, and a sixth line 1320 may correspond to a k^{th} line. In this case, a red subpixel R of a fourth pixel 1315 disposed between the fifth line 1310 and the sixth line 1320 may be connected to the fifth line 1310, and a green subpixel G and a blue subpixel B of the fourth pixel 1315 may be connected to the sixth line 1320.

A pixel capable of emitting light may not be disposed under the sixth line 1320. Therefore, the sixth line 1320 may be connected to only a green subpixel G and a blue subpixel B of a pixel disposed adjacent to the sixth line 1320, including the fourth pixel 1315. In this case, a contact hole connected to a green subpixel G disposed adjacent to the sixth line 1320 may be disposed in the sixth line 1320. A contact hole connected to a red subpixel R may be omitted in the sixth line 1320.

FIG. 14 is a diagram for describing a structure and arrangement of a subpixel of a display apparatus according to various embodiments of the present disclosure.

According to reference numeral 1410 of FIG. 14, a center point of each of a red subpixel R, a green subpixel G, and a blue subpixel B may be arranged to form a triangular shape. According to reference numeral 1410, the red subpixel R and the green subpixel G may have a triangular shape. The blue subpixel B may have a diamond shape.

In an embodiment, each subpixel may be implemented in various shapes. For example, like reference numeral 1420, a red subpixel R and a green subpixel G may have a tetragonal shape, and a blue subpixel B may have a diamond shape. As another example, like reference numeral 1430, a red subpixel R and a green subpixel G may have a trapezoid shape, and a blue subpixel B may have a diamond shape.

However, the arrangement or shape of the subpixel described above with reference FIG. 14 is not limited and may be implemented in various shapes.

In the display apparatus according to an embodiment of the present disclosure, each of subpixels configuring a pixel may be connected to a gate line adjacent thereto, and thus, short circuit may be prevented from occurring when all of subpixels are connected to one gate line.

To provide a detailed description, a red subpixel R and a blue subpixel B among a red subpixel R, a green subpixel G, and a blue subpixel B configuring a pixel of a display apparatus according to an embodiment may be connected to a line (for example, an n^{th} line) disposed on the pixel. On the other hand, the green subpixel G configuring the same pixel may be connected to a line (for example, an n+1^{th} line) disposed under the pixel. In this case, the green subpixel G may not need to extend toward a region between the red subpixel R and the blue subpixel B so as to be connected to the n^{th} line, and thus, a short circuit defect may be prevented.

A display apparatus according to an embodiment of the present disclosure includes: a first driving circuit supplying a gate signal through a first line at a first time and supplying the gate signal through a second line at a second time; a display panel including a first pixel including a first subpixel connected to the first line, a second subpixel connected to the second line, and a third subpixel connected to the first line; and a second driving circuit supplying a data signal to the first subpixel and the third subpixel at the first time and supplying the data signal to the second subpixel at the second time.

Moreover, the first subpixel may correspond to a red subpixel, the second subpixel may correspond to a green subpixel, and the third subpixel may correspond to a blue subpixel.

Moreover, the first subpixel may correspond to a green subpixel, the second subpixel may correspond to a red subpixel, and the third subpixel may correspond to a blue subpixel.

Moreover, the first subpixel may be disposed more upward than the second subpixel in a y axis.

Moreover, a virtual line connecting centers of the first subpixel, the second subpixel, and the third subpixel may be formed in a triangular shape.

Moreover, the first time and the second time may be successive.

Moreover, the first driving circuit may include a gate driver, and the second driving circuit may include a data driver.

Moreover, the display apparatus may include: n+1 number of gate lines connected to the first driving circuit to transfer the gate signal to a plurality of subpixels included in the display apparatus, where n is an integer larger than 1; and m number of data lines connected to the second driving circuit to transfer the data signal to the plurality of subpixels, where m is an integer larger than 1.

Moreover, the n+1 number of gate lines may include the first line and the second line.

Moreover, the first line may be a line disposed at an uppermost end among a plurality of lines connected to the first driving circuit, and the second line may be a line disposed more downward than the first line.

Moreover, the display panel may further include a dummy pixel disposed more upward than the first line, the dummy pixel may be connected to the first line, and a portion at which the dummy pixel contacts the first line may be disposed in the first line.

A display panel according to an embodiment of the present disclosure includes: a first line transferring a gate signal at a first time and a second line transferring the gate signal at a second time; a first pixel including a first subpixel connected to the first line, a second subpixel connected to the second line, and a third subpixel connected to the first line; and a third line transferring a data signal to the first subpixel and the third subpixel at the first time and a fourth line transferring the data signal to the second subpixel at the second time.

Moreover, the first subpixel may correspond to a red subpixel, the second subpixel may correspond to a green subpixel, and the third subpixel may correspond to a blue subpixel.

Moreover, the first subpixel may correspond to a green subpixel, the second subpixel may correspond to a red subpixel, and the third subpixel may correspond to a blue subpixel.

Moreover, the first subpixel may be disposed more upward than the second subpixel in a y axis.

Moreover, a virtual line connecting centers of the first subpixel, the second subpixel, and the third subpixel may be formed in a triangular shape.

Moreover, the first time and the second time may be successive.

Moreover, the first line and the second line may be connected to a first driving circuit, and the third line and the fourth line may be connected to a second driving circuit.

Moreover, the first driving circuit may include a gate driver, and the second driving circuit may include a data driver.

Moreover, the display panel may include: n+1 (where n is a natural number) number of gate lines connected to the first driving circuit to transfer the gate signal to a plurality of subpixels included in the display panel, where n is an integer larger than 1; and m (where m is a natural number) number of data lines connected to the second driving circuit to transfer the data signal to the plurality of subpixels, where m is an integer larger than 1.

Moreover, the n+1 number of gate lines may include the first line and the second line, and the m number of data lines may include the third line and the fourth line.

Moreover, the first line may be a line disposed at an uppermost end among a plurality of lines connected to the first driving circuit, and the second line may be a line disposed more downward than the first line.

Moreover, the display panel may further include a dummy pixel disposed more upward than the first line, the dummy pixel may be connected to the first line, and a portion at which the dummy pixel contacts the first line may be disposed in the first line.

In the display apparatus and the display panel thereof according to the present disclosure, a disconnection of a line may be prevented based on modifying a connection structure so that a line of each of a plurality of subpixels is connected to a line adjacent thereto, thereby enhancing display quality.

The effects according to the present disclosure are not limited to the above examples, and other various effects may be included in the specification.

While the present disclosure has been particularly shown and described with reference to embodiments thereof, it will be understood by those of ordinary skill in the art that various changes in form and details may be made therein without departing from the spirit and scope of the present disclosure as defined by the following claims.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a first driving circuit supplying a gate signal through a first line at a first time and supplying the gate signal through a second line at a second time;
a display panel including a first pixel, the first pixel including:
a first subpixel connected to the first line, a second subpixel connected to the second line, and a third subpixel connected to the first line; and
a second driving circuit supplying a data signal to the first subpixel and the third subpixel at the first time and supplying the data signal to the second subpixel at the second time.

2. The display apparatus of claim 1, wherein the first subpixel is a red subpixel, the second subpixel is a green subpixel, and the third subpixel is a blue subpixel.

3. The display apparatus of claim 1, wherein the first subpixel is a green subpixel, the second subpixel is a red subpixel, and the third subpixel is a blue subpixel.

4. The display apparatus of claim 1, wherein the first subpixel is disposed more upward than the second subpixel in a first axis direction.

5. The display apparatus of claim 1, wherein virtual lines connecting centers of the first subpixel, the second subpixel, and the third subpixel to each other form a triangular shape.

6. The display apparatus of claim 1, wherein the first time and the second time are successive.

7. The display apparatus of claim 1, wherein the first driving circuit comprises a gate driver, and
the second driving circuit comprises a data driver.

8. The display apparatus of claim 1, comprising:
n+1 number of gate lines connected to the first driving circuit to transfer the gate signal to a plurality of subpixels included in the display apparatus, where n is an integer larger than 1; and
m number of data lines connected to the second driving circuit to transfer the data signal to the plurality of subpixels, where m is an integer larger than 1.

9. The display apparatus of claim 8, wherein the n+1 number of gate lines include the first line and the second line.

10. The display apparatus of claim 1, wherein the first line is a line disposed at an uppermost end among a plurality of lines connected to the first driving circuit, and the second line is a line disposed more downward than the first line.

11. The display apparatus of claim 10, wherein the display panel further includes a dummy pixel disposed more upward than the first line,
wherein the dummy pixel is connected to the first line, and a portion at which the dummy pixel contacts the first line is disposed in the first line.

12. A display panel comprising:
a first line transferring a gate signal at a first time;
a second line transferring the gate signal at a second time;
a first pixel including:
a first subpixel connected to the first line, a second subpixel connected to the second line, and a third subpixel connected to the first line; and
a third line transferring a data signal to the first subpixel and the third subpixel at the first time; and
a fourth line transferring the data signal to the second subpixel at the second time.

13. The display panel of claim 12, wherein the first subpixel is a red subpixel, the second subpixel is a green subpixel, and the third subpixel is a blue subpixel.

14. The display panel of claim 12, wherein the first subpixel is a green subpixel, the second subpixel is a red subpixel, and the third subpixel is a blue subpixel.

15. The display panel of claim 12, wherein the first subpixel is disposed more upward than the second subpixel in a first axis direction.

16. The display panel of claim 12, wherein virtual lines connecting centers of the first subpixel, the second subpixel, and the third subpixel form a triangular shape.

17. The display panel of claim 12, wherein the first time and the second time are successive.

18. The display panel of claim 12, wherein the first line and the second line are connected to a first driving circuit, and
the third line and the fourth line are connected to a second driving circuit.

19. The display panel of claim 18, wherein the first driving circuit comprises a gate driver, and
the second driving circuit comprises a data driver.

20. The display panel of claim 12, comprising:
n+1 number of gate lines connected to a first driving circuit to transfer the gate signal to a plurality of subpixels included in the display panel, where n is an integer larger than 1; and
m number of data lines connected to a second driving circuit to transfer the data signal to the plurality of subpixels, where m is an integer larger than 1.

21. The display panel of claim 20, wherein the n+1 number of gate lines include the first line and the second line, and
the m number of data lines include the third line and the fourth line.

22. The display panel of claim 18, wherein the first line is a line disposed at an uppermost end among a plurality of lines connected to the first driving circuit, and the second line is a line disposed more downward than the first line.

23. The display panel of claim 22, wherein the display panel further includes a dummy pixel disposed more upward than the first line,
wherein the dummy pixel is connected to the first line, and a portion at which the dummy pixel contacts the first line is disposed in the first line.
